(19) United States
(12) Patent Application Publication
(10) Pub. No.: US 2025/0185366 A1
(43) Pub. Date: Jun. 5, 2025

(54) DISPLAY PANEL AND DISPLAY TERMINAL

(71) Applicant: TCL CHINA STAR OPTOELECTRONICS TECHNOLOGY CO., LTD., Shenzhen (CN)

(72) Inventors: Litao YANG, Shenzhen (CN); Li CHAI, Shenzhen (CN)

(73) Assignee: TCL CHINA STAR OPTOELECTRONICS TECHNOLOGY CO., LTD., Shenzhen (CN)

(21) Appl. No.: 18/969,025

(22) Filed: Dec. 4, 2024

(30) Foreign Application Priority Data
Dec. 4, 2023 (CN) 202311656446.5

(51) Int. Cl. H10D 86/40

(52) U.S. Cl. CPC H10D 86/451; H10D 86/441

(57) ABSTRACT

The present application discloses a display panel and a display terminal. The display panel includes a display part and a bonding part located on a side of the display part. The bonding part includes bonding terminals and a bonding member, the bonding member is bonded to and connected to the bonding terminals. The bonding member includes at least one exposed metal surface, and the metal surface is a first end surface. The display panel further includes a shielding element, the shielding element is disposed between the bonding part and the display part, and the shielding element is a conductor. The bonding member and the display part are disposed insulatively from the shielding element, and the shielding element at least covers the first end surface.

### CROSS REFERENCE TO RELATED APPLICATIONS

This application claims priority to Chinese Patent Application No. 202311656446.5, filed on Dec. 4, 2023. The entire disclosures of the above application are incorporated herein by reference.

### FIELD OF INVENTION

The present application relates to a field of display technologies, especially to a display panel and a display terminal.

### BACKGROUND OF INVENTION

In a display panel, input signals can be input into the display panel through bonding members, such as a chip on film, a driver chip, or a flexible printed circuit board. The bonding member has an exposed metal surface, and this metal surface forms an electrical field with electrodes and other components within the display panel. This can easily lead to electrochemical corrosion of the metal surface, resulting in abnormal display.

Therefore, electrochemical corrosion of the bonding member is one of the technical issues that professionals in this field urgently need to resolve.

### SUMMARY OF INVENTION

The present application provides a display panel and a display terminal to solve a technical issue of abnormal display due to electrochemical corrosion of the bonding member.

To solve the above technical issue, the present application provides technical solutions as follows:

The present application provides a display panel, comprising a display part and a bonding part located on a side of the display part; wherein the bonding part comprises:
a plurality of bonding terminals; and
a bonding member bonded and connected to the bonding terminals, wherein the bonding member comprises at least one exposed metal surface, and the metal surface is a first end surface; and
wherein the display panel further comprises a shielding element disposed between the bonding part and the display part;
wherein the shielding element is a conductor, the bonding member and the display part are disposed insulatively from the shielding element, and the shielding element at least covers the first end surface.

In the display panel of the present application, the display part comprises a first electrode, the bonding member comprises a plurality of connection wirings, and the connection wirings is bonded and connected to the bonding terminals; and
an end surface of the connection wiring near the first electrode is the first end surface, and the first end surface is exposed out of a sidewall of the bonding member.

In the display panel of the present application, the display panel comprises:
a first substrate;
a second substrate comprising an opposite part and an extension portion connected together, wherein the opposite part is spaced from and opposite to the first substrate;
wherein the first electrode is disposed on a side surface of the first substrate, an orthographic projection of the first electrode on the second substrate does not overlap the extension portion; the display part comprises the first substrate and the opposite part, the bonding part comprises the extension portion; an end of the shielding element overlaps the extension portion, and another end of the shielding element overlaps the bonding member.

In the display panel of the present application, the first end surface is flush with a side surface of the bonding member near the first substrate, the bonding part further comprises a conductive adhesive, and the conductive adhesive is disposed between the bonding member and the bonding terminals; and
the conductive adhesive covers the bonding terminals, and an end of the conductive adhesive near the first substrate protrudes from the first end surface.

In the display panel of the present application, the conductive adhesive at least covers the first end surface, and the shielding element covers an end of the conductive adhesive near the first substrate.

In the display panel of the present application, an end of the conductive adhesive away from the first substrate covers a part of a sidewall of the extension portion away from the first substrate, an end of the bonding member away from the first substrate protrudes from an end of the conductive adhesive away from the first substrate.

In the display panel of the present application, an orthographic projection of the shielding element on the second substrate is located within the extension portion, and a projection area of the shielding element on the second substrate is less than an area of the extension portion.

In the display panel of the present application, the display panel further comprises protective adhesive, the protective adhesive covers the shielding element, and the orthographic projection of the shielding element on the second substrate is located within an orthographic projection of the protective adhesive on the second substrate.

In the display panel of the present application, an insulation adhesive is disposed on a side of the shielding element near the first end surface, the shielding element is bonded to the second substrate and the bonding member through the insulation adhesive.

The present application also provides a display terminal, and the display terminal comprises the above display panel.

Advantages: the present application discloses a display panel and a display terminal. The display panel comprises a display part and a bonding part located on side of the display part. The bonding part comprises a plurality of bonding terminals, bonding member. The bonding member is bonded to and connected to the bonding terminals. The bonding member comprises at least one exposed metal surface. The metal surface is a first end surface. The display panel further comprises a shielding element. The shielding element is disposed between the bonding part and the display part. The shielding element is a conductor. The bonding member and the display part are disposed insulatively from the shielding element, and the shielding element at least covers the first end surface. The present application disposes a shielding element between the bonding member and the display part. The shielding element is a conductor. The bonding member and the display part are disposed insulatively from the shielding element, and the shielding element covers the bonding member exposed metal surface. The shielding element can shield an electrical field of the display part and a first end surface of the bonding member, thereby preventing electrochemical corrosion occurring on the first end surface under an effect of the electrical field.

### DESCRIPTION OF DRAWINGS

Specific embodiments of the present invention are described in details with accompanying drawings as follows to make technical solutions and advantages of the present invention clear.

FIG. 1 is a schematic structural top view of a display panel provided by an embodiment of the present application;

FIG. 2 is a schematic cross-sectional structural view along a line B-B in FIG. 1;

FIG. 3 is a schematic partial structural view in FIG. 1;

FIG. 4 is a schematic structural view omitting a shielding element.

### Indication of Reference Numerals

display part 1, display region AA, non-display region NA, first substrate 10, first electrode 11, opposite part 12, bonding part 2, bonding terminals 21, extension portion 22, sidewall 22a of extension portion, bonding member 30, connection wirings 31, first end surface 31a, base layer 32, second substrate 20, the insulation layer 23, shielding element 40, insulation adhesive 41, conductive adhesive 50, the adhesive layer 51, conductive particle 52, protective adhesive 60, frame sealant 70.

### DETAILED DESCRIPTION OF PREFERRED EMBODIMENTS

The technical solution in the embodiment of the present application will be clearly and completely described below with reference to the accompanying drawings in the embodiments of the present application. Apparently, the described embodiments are merely some embodiments of the present application instead of all embodiments. According to the embodiments in the present application, all other embodiments obtained by those skilled in the art without making any creative effort shall fall within the protection scope of the present application. In addition, it should be understood that the specific embodiments described here are only used to illustrate and explain the present application, and are not used to limit the present application. In the present application, the used orientation terminologies such as “upper” and “lower”, when not specified to the contrary explanation, usually refer to the upper and lower states of the device in actual use or working conditions, specifically according to the direction of the figures in the drawings. Furthermore, “inner” and “outer” refer to the outline of the device.

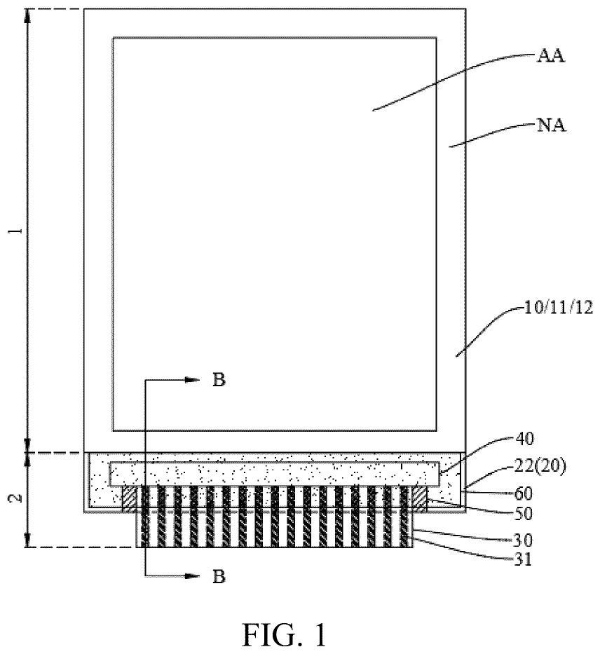

The present application provides a display panel. With reference to FIGS. 1 to 3, the display panel comprises a display part 1 and a bonding part 2 located on a side of the display part 1. The bonding part 2 comprises a plurality of bonding terminals 21 and a bonding member 30. The bonding member 30 is bonded to and connected to the bonding terminals 21. The bonding member 30 comprises at least one exposed metal surface, metal surface is a first end surface 31a. The display panel further comprises a shielding element 40. The shielding element 40 is disposed between the bonding part 2 and the display part 1. The shielding element 40 is a conductor. The bonding member 30 and the display part 1 are disposed insulatively from the shielding element 40, and the shielding element 40 at least covers the first end surface 31a.

In the present embodiment, the display panel can be a liquid crystal display panel, an electronic paper, an organic light emitting diode (OLED) display panel, a mini-LED display panel, or a micro-LED display panel.

In the present embodiment, the display part 1 can be configured to display screen images, the display part 1 comprises a display region AA and a non-display region NA located on an outer periphery of the display region AA. The display region AA can be configured to screen images. A plurality of pixels are disposed in the display region AA, and the pixel can comprise a red subpixel, a green subpixel, and a blue subpixel.

The display part 1 is connected to the bonding part 2. The bonding part 2 comprises the bonding terminals 21. an end of the bonding terminal 21 is bonded to and connected to the bonding member 30, another end of the bonding terminal 21 is connected to the display part 1 through a connection line. The connection line can transmit a signal, input from the bonding member 30 to the bonding terminals 21, to the display part 1, thereby driving the display part 1 to display screen images.

The bonding member 30 comprises at least one exposed metal surface, the exposed metal surface refers to an outer surface of the metal surface exposed out of the bonding member 30 and not covered by other part of the bonding member 30. For example, the bonding member 30 can comprise a metal wiring, and a sectional surface of the metal wiring is exposed out from a sidewall of the bonding member 30. The bonding member 30 can also comprise a metal soldering pad. A surface of the metal soldering pad is exposed on a surface of the bonding member 30. For convenience of description, the exposed metal surface of the bonding member 30 is called the first end surface 31a.

The display part 1 comprises a plurality of metal film layers. During working of the display panel, the metal film layer receives a first voltage signal. The bonding member 30 input a signal to the display panel, and the first end surface 31a of the bonding member 30 receives a second voltage signal. It should be understood that various voltage signals exist in the display panel. In certain situations, the first voltage signal and the second voltage signal are different. At this time, an electric field will form between the metal film layers and the first end surface 31a. During long-term use, the display panel, under the influence of the electric field and moisture, will experience electrochemical corrosion, leading to the corrosion of the first end surface 31a. When the first end surface 31a includes a plurality of metal surfaces near each other, adjacent metal surfaces are prone to short-circuit due to corrosion, affecting the functionality of the display panel.

In the present embodiment, the bonding member 30 can be a chip on film, flexible printed circuit board, but no limit is thereto.

In the present embodiment, the shielding element 40 is a conductor able to be configured to shield an electrical field between the bonding part 2 and the display part 1. For example, material of the shielding element 40 can be metal such as aluminum, copper, or tin. A shape of the shielding element 40 can be metal sheet, thereby not only performing the function of shielding the electrical field but also having no influence on an overall thickness of the bonding part 2. For example, the shielding element 40 can be aluminum foil, copper foil, or tin foil.

The shielding element 40 at least covers the first end surface 31a and the shielding element 40. The bonding member 30 and the display part 1 are insulated from each other. Because the shielding element 40 is located between the display part 1 and the bonding member 30, it can shield the electrical field formed between the display part 1 and the bonding member 30, thereby preventing electrochemical corrosion from occurring on the bonding member 30.

In the display panel of the present application, with reference to FIGS. 1 to 3, the display part 1 comprises a first electrode 11. The bonding member 30 comprises a plurality of connection wirings 31, and the connection wirings 31 are bonded to and connected to the bonding terminals 21. An end surface of the connection wirings 31 near the first electrode 11 is the first end surface 31a. The first end surface 31a is exposed out of the bonding member 30.

In the present embodiment, the display part 1 comprises the first electrode 11, and the first electrode 11 can be configured to input a voltage signal. The first electrode 11 can be a common electrode.

Material of the first electrode 11 can be metal or metal oxide, for example, molybdenum, aluminum, copper, indium tin oxide (ITO), indium zinc oxide (IZO), indium zinc tin oxide (IZTO), but no limit is thereto.

In the present embodiment, the bonding member 30 comprises a plurality of the connection wirings 31, each of the connection wirings 31 is bonded to and connected to one of the bonding terminals 21. An orthographic projection of the bonding terminals 21 on the extension portion 22 overlaps an orthographic projection of the connection wirings 31 on the extension portion 22. Material of the connection wirings 31 is conductive material, for example, metal copper, but no limit is thereto.

The bonding member 30 comprises a base layer, and the base layer provide the connection wirings 31 with a carrier.

The connection wirings 31 can comprise an exposed metal surface. For example, the bonding member 30 is a chip on film, the chip on film is formed by cutting during manufacturing. The connection wirings 31 of the chip on film are cut at the cutting part to form the exposed metal surface. The exposed metal surface is the first end surface 31a, and the first end surface 31a is exposed out of a sidewall of the bonding member 30. After electrochemical corrosion occurs on the bonding member 30, the connection wirings 31 of the first end surface 31a loses electrons, and electrons in a free state are electrically connected to the connection wirings 31 to form a short circuit, thereby resulting in abnormal display of screen images.

In the display panel of the present application, with reference to FIGS. 1 to 3, the display panel comprises a first substrate 10 and a second substrate 20. The second substrate 20 comprises an opposite part 12 and an extension portion 22 connected together. The opposite part 12 is spaced from and opposite to the first substrate 10. The first electrode 11 is disposed on a side surface of the first substrate 10. An orthographic projection of the first electrode 11 on the second substrate 20 does not overlap the extension portion 22. The display part 1 comprises the first substrate 10 and the opposite part 12. The bonding part 2 comprises the extension portion 22. An end of the shielding element 40 overlaps the extension portion 22, and another end of the shielding element 40 overlaps the bonding member 30.

In the present embodiment, the display panel [symbol] liquid crystal display panel or electronic paper. The first substrate 10 and the second substrate 20 can be the same or different material. For example, the first substrate 10, the second substrate 20 can be one of glass, polyimide, polyethylene terephthalate, or polycarbonate.

When the display panel is a liquid crystal display panel, the display panel further comprises a backlight module. The backlight module is disposed on a side of the second substrate 20 away from the first substrate 10. The backlight module is configured to provide an area light source.

When the display panel is an electronic paper, the display panel uses incident ambient light entering a side of the first substrate 10 to display.

In the present embodiment, the second substrate 20 comprises the opposite part 12 and the extension portion 22 connected together. The opposite part 12 and the extension portion 22 can be disposed integrally.

Along a direction parallel to the display surface, an area of the second substrate 20 can be greater than an area of the first substrate 10. Namely, an orthographic projection of the first substrate 10 on the second substrate 20 is located within the second substrate 20. For example, an orthographic projection of the first substrate 10 on the second substrate 20 can coincide with the opposite part 12.

The first electrode 11 can be disposed on a side surface of the first substrate 10 near the second substrate 20. A pixel electrode can be disposed on a side surface of the second substrate 20 near the first substrate 10. The display medium, under the effect of the electrical field formed between the first electrode 11 and the pixel electrode, is configured to display.

An array layer (not shown) can also be disposed on the second substrate 20. The array layer comprises a driver circuit. The driver circuit is configured to drive pixels of the display panel to display. An insulation layer 23 is disposed on a side of the second substrate 20 near the first substrate 10. A plurality of apertures are disposed on the insulation layer 23. Each of the apertures corresponds to one of the bonding terminals 21. A side surface of the bonding terminals 21 away from the insulation layer 23 is exposed and is configured to be bonded to and connected to the bonding member 30.

In the present embodiment, the first substrate 10 can be color filter substrate, the second substrate 20 can be array substrate.

In the present embodiment, a display medium can be disposed between the first substrate 10 and the opposite part 12. The display medium can be liquid crystal or electrophoretic substances. The display part 1 further comprises a frame sealant 70, the frame sealant 70 is disposed between the first substrate 10 and the opposite part 12. The frame sealant 70 is arranged in a loop, and the frame sealant 70 is configured to implement a seal to the display medium.

In the present embodiment, along a direction from the display part 1 to the bonding part 2, an end of the shielding element 40 overlaps the extension portion 22, and another end of the shielding element 40 overlaps the bonding member 30. Namely, an end of the shielding element 40 can contact the extension portion 22, and another end of the shielding element 40 can contact a side of the bonding member 30 away from the bonding terminals 21. The first end surface 31a is connected to a side of the bonding member 30 away from the bonding terminals 21. By the above configuration, the shielding element 40 can completely cover the first end surface 31a. In one aspect, the shielding element 40 can shield the electrical field between the first electrode 11 and the connection wirings 31. In another aspect, the shielding element 40 can also prevent water vapor from contacting the first end surface 31a.

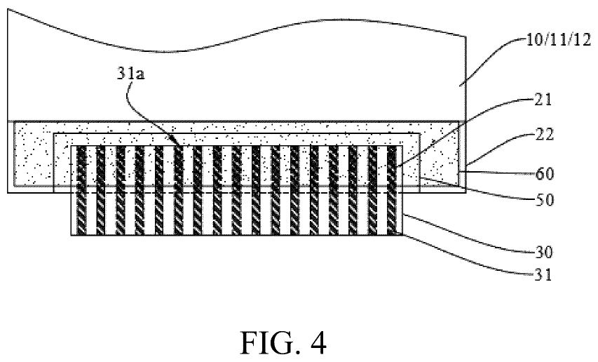

In the display panel of the present application, with reference to FIG. 4, FIG. 4 omits the shielding element 40 to explain the structure of a conductive adhesive 50 and the bonding member 30. The first end surface 31a is flush with a side surface of the bonding member 30 near the first substrate 10. The bonding part 2 further comprises a conductive adhesive 50. The conductive adhesive 50 is disposed between the bonding member 30 and the bonding terminals 21. The conductive adhesive 50 covers the bonding terminals 21, and an end of the conductive adhesive 50 near the first substrate 10 protrudes from the first end surface 31a.

In the present embodiment, the first end surface 31a is flush with the side surface of the bonding member 30 near the first substrate 10. In other words, the first end surface 31a does not extend beyond a sidewall of the bonding member 30.

In the present embodiment, the conductive adhesive 50 can be an anisotropic conductive adhesive, but no limit is thereto. The conductive adhesive 50 comprises an adhesive layer 51 and a plurality of conductive particles 52. The conductive particles 52 are distributed in the adhesive layer 51. After bonded and press-fitted, the conductive particles 52 are squeezed, an insulation film of a surface layer of the conductive particles 52 is ruptured. Along a direction perpendicular to a plane of the extension portion 22, the conductive particles 52 contacts the bonding terminals 21 and the connection wirings 31 to for electrical connection. Along a direction parallel to the plane of the extension portion 22, adjacent two of the conductive particles 52 are insulated.

In the present embodiment, the conductive adhesive 50 covers the bonding terminals 21, namely, an orthographic projection of the bonding terminals 21 on the conductive adhesive 50 is located within the conductive adhesive 50. By the above configuration, a press-fitting area of the bonding terminals 21 and the bonding member 30 becomes greater, which improves the bonding effect. After the bonding member 30 is bonded to and connected to the bonding terminals 21, the adhesive body of the conductive adhesive 50 overflows due to pressure, and the conductive adhesive 50 further extends beyond the first end surface 31a.

Furthermore, in the present embodiment, because a part of the conductive adhesive 50 extending beyond the first end surface 31a is not squeezed by a force along the direction perpendicular to the extension portion 22 direction, a thickness of the part of the conductive adhesive 50 is greater than a thickness of another part suffering the pressure. The part of the conductive adhesive 50 extending beyond the first end surface 31a would at least cover the first end surface 31a, thereby improving a waterproof effect of the first end surface 31a.

Also, the part of the conductive adhesive 50 extending beyond the first end surface 31a can raise the shielding element 40, thereby preventing the shielding element 40 from directly contacting the first end surface 31a and resulting in a short circuit.

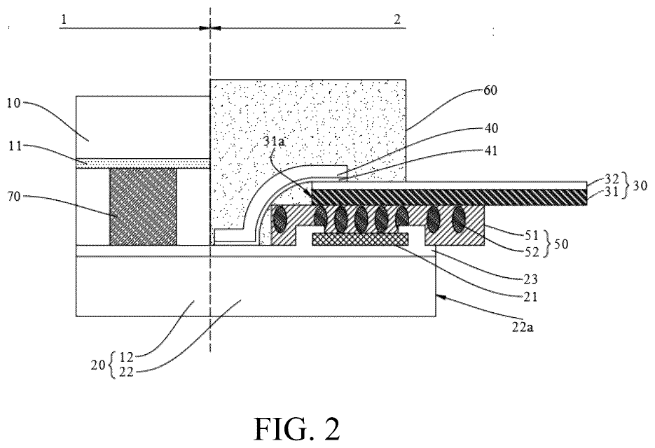

In the display panel of the present application, with reference to FIG. 2, an end of the conductive adhesive 50 away from the first substrate 10 covers a part of a sidewall of the extension portion 22 away from the first substrate 10. An end of the bonding member 30 away from the first substrate 10 protrudes from an end of the conductive adhesive 50 away from the first substrate 10. By the above configuration, in one aspect, the conductive adhesive 50 is able to completely cover the bonding terminals 21 to increase a press-fitting area of the bonding terminals 21 and the bonding member 30. In another aspect, the conductive adhesive 50, after covering a sidewall 22a of the extension portion, enables the conductive adhesive 50 to space the bonding member 30 from the sidewall 22a of the extension portion, thereby preventing the bonding member 30 from rubbing against the sidewall 22a of the extension portion and resulting in damage to the bonding member 30.

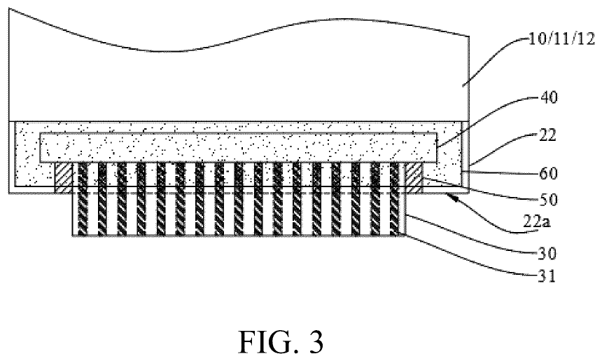

In the display panel of the present application, with reference to FIGS. 1 and 3, an orthographic projection of the shielding element 40 on the second substrate 20 is located within the extension portion 22, and a projection area of the shielding element 40 on the second substrate 20 is less than an area of the extension portion 22. By the above configuration, the shielding element 40 can be prevented from shieling the display part 1 and affecting the display. Also, an area of the shielding element 40 is less than an area of the extension portion 22. Therefore, along a direction parallel to the extension portion 22, the shielding element 40 can be not to extend beyond the extension portion 22.

In the display panel of the present application, with reference to FIGS. 1 to 3, the display panel further comprises a protective adhesive 60. The protective adhesive 60 covers the shielding element 40. An orthographic projection of the shielding element 40 on the second substrate 20 is located within an orthographic projection of the protective adhesive 60 on the second substrate 20.

In the present embodiment, the protective adhesive 60 can repel water vapor and prevent water vapor from contacting the first end surface 31a of the bonding member 30. The protective adhesive 60 can be a Tuffy adhesive, but no limit is thereto.

In the present embodiment, an orthographic projection of the protective adhesive 60 on the second substrate 20 can substantially coincide with the extension portion 22. Namely, the protective adhesive 60 can cover an entire surface of the extension portion 22.

It should be explained that the inventor of the present application discovers that the Tuffy adhesive can effectively repel water vapor. However, after a long time, the water vapor can still seep into the first end surface 31a. Also, water vapor seeps into the conductive adhesive 50 and the frame sealant 70. Therefore, Tuffy adhesive still cannot repel the water vapor for a long time.

In the present embodiment, the shielding element 40 covers the first end surface 31a. The protective adhesive 60 covers the shielding element 40. Disposing the shielding element 40 and the protective adhesive 60 can achieve double protection. Even some of water vapor enters the first end surface 31a, the shielding element 40 can shield the electrical field between the first electrode 11 [symbol] the connection wirings 31 so electrochemical corrosion cannot occur on the first end surface 31a, thereby lowering a risk of electrochemical corrosion occurring on the connection wirings 31 of the bonding member 30.

The shielding element 40, when electrically connected to the first end surface 31a, loses a shielding function. Regarding the above issue, in the display panel of the present application, an insulation adhesive 41 is disposed on the shielding element 40 near the first end surface 31a. The shielding element 40 is bonded to the second substrate 20 and the bonding member 30 through the insulation adhesive 41. Namely, the insulation adhesive 41 is a double sided tape, thereby able to implement bonding of the shielding element 40 with the second substrate 20 and the bonding member 30. The insulation adhesive 41 can be disposed on an entire surface of the shielding element 40, thereby enabling the shielding element 40 able to be completely bonded by the bonding surface to improve an water vapor repellent effect.

It should be understood that although a partial surface of the first end surface 31a is covered by the conductive adhesive 50 and has an insulation effect. However, a partial surface of the first end surface 31a is not covered by the conductive adhesive 50. Disposing the insulation adhesive 41 on a surface of the shielding element 40 near the first end surface 31a can further prevent the first end surface 31a from electrically connected to the shielding element 40.

The present application also provides a display terminal, and the display terminal comprises the above display panel.

In the present embodiment, display terminal can be: any product or component including a display function such as cell phone, tablet, television, display device, notebook, digital photo frame, or navigator.

In the above-mentioned embodiments, the descriptions of the various embodiments are focused. For the details of the embodiments not described, reference may be made to the related descriptions of the other embodiments.

The display panel and the display terminal provided by the embodiment of the present application are described in detail as above. In the present specification, principles and embodiments of the present application are described using specific examples. The principles and implementations of the present application are described in the following by using specific examples. The description of the above embodiments is only for assisting understanding of the technical solutions of the present application and the core ideas thereof. Those of ordinary skill in the art should understand that they can still modify the technical solutions described in the foregoing embodiments or equivalently replace some of the technical features. These modifications or replacements do not make the essence of the technical solutions depart from a range of the technical solutions of the embodiments of the present application.

1. A display panel, comprising a display part and a bonding part located on a side of the display part; wherein the bonding part comprises:
a plurality of bonding terminals; and
a bonding member bonded and connected to the bonding terminals, wherein the bonding member comprises at least one exposed metal surface, and the metal surface is a first end surface; and
wherein the display panel further comprises a shielding element disposed between the bonding part and the display part;
wherein the shielding element is a conductor, the bonding member and the display part are disposed insulatively from the shielding element, and the shielding element at least covers the first end surface.

2. The display panel according to claim 1, wherein
the display part comprises a first electrode, the bonding member comprises a plurality of connection wirings, and the connection wirings is bonded and connected to the bonding terminals; and
an end surface of the connection wiring near the first electrode is the first end surface, and the first end surface is exposed out of a sidewall of the bonding member.

3. The display panel according to claim 2, further comprising:
a first substrate;
a second substrate comprising an opposite part and an extension portion connected together, wherein the opposite part is spaced from and opposite to the first substrate;
wherein the first electrode is disposed on a side surface of the first substrate, an orthographic projection of the first electrode on the second substrate does not overlap the extension portion; the display part comprises the first substrate and the opposite part, the bonding part comprises the extension portion; an end of the shielding element overlaps the extension portion, and another end of the shielding element overlaps the bonding member.

4. The display panel according to claim 3, wherein
the first end surface is flush with a side surface of the bonding member near the first substrate, the bonding part further comprises a conductive adhesive, and the conductive adhesive is disposed between the bonding member and the bonding terminals; and
the conductive adhesive covers the bonding terminals, and an end of the conductive adhesive near the first substrate protrudes from the first end surface.

5. The display panel according to claim 4, wherein the conductive adhesive at least covers the first end surface, and the shielding element covers an end of the conductive adhesive near the first substrate.

6. The display panel according to claim 4, wherein an end of the conductive adhesive away from the first substrate covers a part of a sidewall of the extension portion away from the first substrate, an end of the bonding member away from the first substrate protrudes from an end of the conductive adhesive away from the first substrate.

7. The display panel according to claim 3, wherein an orthographic projection of the shielding element on the second substrate is located within the extension portion, and a projection area of the shielding element on the second substrate is less than an area of the extension portion.

8. The display panel according to claim 7, wherein the display panel further comprises protective adhesive, the protective adhesive covers the shielding element, and the orthographic projection of the shielding element on the second substrate is located within an orthographic projection of the protective adhesive on the second substrate.

9. The display panel according to claim 3, wherein an insulation adhesive is disposed on a side of the shielding element near the first end surface, the shielding element is bonded to the second substrate and the bonding member through the insulation adhesive.

10. A display terminal, wherein the display terminal comprises a display panel, the display panel comprises a display part and a bonding part located on a side of the display part; wherein the bonding part comprises:
a plurality of bonding terminals; and
a bonding member bonded and connected to the bonding terminals, wherein the bonding member comprises at least one exposed metal surface, and the metal surface is a first end surface; and
wherein the display panel further comprises a shielding element disposed between the bonding part and the display part;
wherein the shielding element is a conductor, the bonding member and the display part are disposed insulatively from the shielding element, and the shielding element at least covers the first end surface.

11. The display terminal according to claim 10, wherein
the display part comprises a first electrode, the bonding member comprises a plurality of connection wirings, and the connection wirings is bonded and connected to the bonding terminals; and
an end surface of the connection wiring near the first electrode is the first end surface, and the first end surface is exposed out of a sidewall of the bonding member.

12. The display terminal according to claim 11, further comprising:
a first substrate;
a second substrate comprising an opposite part and an extension portion connected together, wherein the opposite part is spaced from and opposite to the first substrate;
wherein the first electrode is disposed on a side surface of the first substrate, an orthographic projection of the first electrode on the second substrate does not overlap the extension portion; the display part comprises the first substrate and the opposite part, the bonding part comprises the extension portion; an end of the shielding element overlaps the extension portion, and another end of the shielding element overlaps the bonding member.

13. The display terminal according to claim 12, wherein
the first end surface is flush with a side surface of the bonding member near the first substrate, the bonding part further comprises a conductive adhesive, and the conductive adhesive is disposed between the bonding member and the bonding terminals; and
the conductive adhesive covers the bonding terminals, and an end of the conductive adhesive near the first substrate protrudes from the first end surface.

14. The display terminal according to claim 13, wherein the conductive adhesive at least covers the first end surface, and the shielding element covers an end of the conductive adhesive near the first substrate.

15. A display panel, comprising a display part and a bonding part located on a side of the display part; wherein the bonding part comprises:
a plurality of bonding terminals; and
a bonding member bonded and connected to the bonding terminals, wherein the bonding member comprises at least one exposed metal surface, and the metal surface is a first end surface; and
wherein the display panel further comprises a shielding element disposed between the bonding part and the display part;
wherein the shielding element is a conductor, the bonding member and the display part are disposed insulatively from the shielding element, and the shielding element at least covers the first end surface;
wherein the display part comprises a first electrode, the bonding member comprises a plurality of connection wirings, and the connection wirings is bonded and connected to the bonding terminals;
wherein an end surface of the connection wiring near the first electrode is the first end surface, and the first end surface is exposed out of a sidewall of the bonding member;
wherein the display panel further comprising:
a first substrate;
a second substrate comprising an opposite part and an extension portion connected together, wherein the opposite part is spaced from and opposite to the first substrate;
wherein the first electrode is disposed on a side surface of the first substrate, an orthographic projection of the first electrode on the second substrate does not overlap the extension portion; the display part comprises the first substrate and the opposite part, the bonding part comprises the extension portion; an end of the shielding element overlaps the extension portion, and another end of the shielding element overlaps the bonding member;
wherein an orthographic projection of the shielding element on the second substrate is located within the extension portion, and a projection area of the shielding element on the second substrate is less than an area of the extension portion.

16. The display panel according to claim 15, wherein
the first end surface is flush with a side surface of the bonding member near the first substrate, the bonding part further comprises a conductive adhesive, and the conductive adhesive is disposed between the bonding member and the bonding terminals; and
the conductive adhesive covers the bonding terminals, and an end of the conductive adhesive near the first substrate protrudes from the first end surface.

17. The display panel according to claim 16, wherein the conductive adhesive at least covers the first end surface, and the shielding element covers an end of the conductive adhesive near the first substrate.

18. The display panel according to claim 16, wherein an end of the conductive adhesive away from the first substrate covers a part of a sidewall of the extension portion away from the first substrate, an end of the bonding member away from the first substrate protrudes from an end of the conductive adhesive away from the first substrate.

19. The display panel according to claim 15, wherein the display panel further comprises protective adhesive, the protective adhesive covers the shielding element, and the orthographic projection of the shielding element on the second substrate is located within an orthographic projection of the protective adhesive on the second substrate.

20. The display panel according to claim 15, wherein an insulation adhesive is disposed on a side of the shielding element near the first end surface, the shielding element is bonded to the second substrate and the bonding member through the insulation adhesive.
